(19) United States
(12) Patent Application Publication
(10) Pub. No.: US 2002/0078411 A1
(43) Pub. Date: Jun. 20, 2002

(54) Scan flip flop apparatus for performing speed test

(76) Inventor: Manuel Antonio D'Abreu, El Dorado Hills, CA (US)

Correspondence Address: Merchant & Gould P.C., P.O. Box 2903, Minneapolis, MN, 55402-0903, US

(21) Appl. No.: 09/728,842

(22) Filed: Dec. 1, 2000

(51) Int. Cl. G01R 31/28

(52) U.S. Cl. 714/727

(57) ABSTRACT

A flip flop apparatus in a scan chain for a Design-for-Test system includes a logic device wherein whenever a scan shifting occurs, the flip flop register disables any changes at its output to a combinational logic of a circuit under test, thereby allowing speed testing of the circuit without increasing in power usage and/or heating in the circuit.

### TECHNICAL FIELD

The present invention relates in general to a scan flip flop apparatus for performing speed test, and more particularly, to a scan flip flop apparatus that allows the use of a scan chain to perform speed test while preventing increase in power dissipation during a scan-enable operation.

### BACKGROUND OF THE INVENTION

In designing integration circuits (IC), particularly in designing very large scale integration (VLSI) circuits, testing circuits to screen out bad devices has become an important and inevitable step. A collection of testing techniques has been developed over the years. Among these testing techniques, scan design using a scan chain is the most popular one.

Scan design is a Design-for-Test (DFT) technique that enables automatic generation of manufacturing test to screen out bad devices or logics in a circuit. Bad devices or logics occur due to the presence of random defects. To aid the generation of test vectors, these defects are modeled as “Stuck-at” faults, for example, “Stuck-at-1” or “Stuck-at-0” faults. Scan design allows the automatic generation of tests so as to achieve extremely high coverage, e.g. >99%, of these faults or defects.

Several scan designs have been proposed for performing speed testing. In one proposal, a scan chain is configured as a Linear Feedback Shift Register (LFSR) that can be run at speed and uses pseudo random test vectors. Another proposal is to use multiple latch design for scan that requires more than one clock to capture test results. This is the Level Sensitive Scan Design (LSSD). An additional proposal is to use clocked scan and muxed-scan designs for speed testing.

However, these techniques do not support at-speed scan operations. In these techniques, the scan operations are not performed at the speed that a device is designed to operate. These existing scan design techniques require that the scan operations be performed at a much lower speed, typically at least 10-15% slower than the functional speed that the device is designed to operate. One reason for this is that during a scan-enable operation, i.e. scan-in of test data, the shifting of test vectors through a scan chain has unpredictable side effects on a circuit. These side effects are primarily caused by increasing in power dissipation due to the activity created in the circuit under test and the complexity of applying deterministic tests targeted to speed paths, and observing the results after propagating the tests through the circuit in a single clock cycle. As a result, the speed of scan operations is much slower than the functional speed that a device is designed to operate. The existing scan design techniques are, therefore, not geared to allow testing of speed paths or referred to as critical paths.

It is with respect to these or other considerations that the present invention has been made.

### SUMMARY OF THE INVENTION

In accordance with this invention, the above and other problems were solved by providing a scan flip flop apparatus that allows the use of a scan chain to perform speed test while preventing increase in power dissipation during a scan-enable operation.

The present invention provides a scan flip flop apparatus capable of performing scan tests at speed and applying the scan tests to a speed path of a circuit. The speed path of a circuit can be tested in a single clock cycle. The present invention also solves the problems of the increase in power dissipation and circuit temperature caused by the activities within a circuit during shifting of scan vectors through a scan chain. The scan flip flop apparatus prevents propagation of signals from the scan flip flop apparatus into a circuit under test during a scan shift or scan-enable operation. The scan flip flop apparatus prevents propagation of spurious data through the circuit and enables the scan-in of scan test vectors to be performed at speed, i.e. the speed that the circuit is designed to operate.

In one embodiment of the present invention, a flip flop apparatus used in a scan chain includes: a flip flop logic clocked by a clock signal, a mux for muxing a data-in signal and a scan-in signal and outputting either the data-in signal when a scan-enable control signal enables the data-in signal during a data-enable operation or the scan-in signal when the scan-enable control signal enables the scan-in signal during a scan-enable operation, an output of the mux being sent to the flip flop logic, and a logic device having a first input which receives an output of the flip flop logic and a second input which receives the scan-enable control signal. During the scan-enable operation, an output of the logic device is logic Zero.

Further in one embodiment, during the data-enable operation, the output of the logic device is the output of the flip flop logic.

Still in one embodiment, the logic device is an AND gate.

Also, the present invention provides a scan chain apparatus used in a Design-for-Test (DFT) system. In one embodiment, the scan chain includes at least three flip flop registers connected in series, and at least one combinational logic connected to the at least three flip flop registers for receiving/sending signals from/to the at least three flip flop registers. Each of the flip flop registers includes: a flip flop logic clocked by a clock signal, a mux for muxing a data-in signal and a scan-in signal and outputting either the data-in signal when a scan-enable control signal enables the data-in signal during a data-enable operation or the scan-in signal when the scan-enable control signal enables the scan-in signal during a scan-enable operation, an output of the mux being sent to the flip flop logic, and a logic device having a first input which receives an output of the flip flop logic and a second input which receives the scan-enable control signal. An output of the logic device is sent to the combinational logic. During the scan-enable operation, the output of the logic device is logic Zero.

Further in one embodiment, during the data-enable operation, the output of the logic device is the output of the flip flop logic.

Still in one embodiment, the logic device is an AND gate.

The present invention also provides a method of testing a circuit at speed in a scan chain apparatus used in a Design-for-Test (DFT) system. In one embodiment, the method includes the steps of: providing a plurality of flip flop registers connected in series; shifting test data into a combinational logic of the circuit via the flip flop registers; and outputting logic Zero from the flip flop registers to the combinational logic during a scan-enable operation.

Further in one embodiment, the method includes the step of outputting a flip flop logic from the flip flop registers to the combinational logic during a data-enable operation.

Still in one embodiment, the step of outputting logic Zero includes providing an AND gate, and the AND gate outputs logic Zero during the scan-enable operation.

One advantage of the present invention is that the scan shifting can be performed at a circuit clock speed, thus allowing for performing speed test. Also, since the input into the combinational logic is logic Zero during the scan-enable operation, the flip flop registers disable any change at the output of the scan chain. Thus, no signals are propagated through the combinational logic during the scan-enable operation. Therefore, there is no logic activity in the combinational logic, and thereby no increase in power usage or heating of a circuit.

These and various other advantages and features of novelty which characterize the invention are pointed out with particularity in the claims annexed hereto and form a part hereof. However, for a better understanding of the invention, its advantages, and the objects obtained by its use, reference should be made to the drawings which form a further part hereof, and to accompanying descriptive matter, in which there are illustrated and described specific examples of an apparatus in accordance with the invention.

### BRIEF DESCRIPTION OF THE DRAWINGS

Referring now to the drawings in which like reference numbers represent corresponding parts throughout:

FIG. 1 illustrates a schematic circuit diagram of one embodiment of a scan chain apparatus used in a Design-for-Test (DFT) system.

FIG. 2 illustrates a schematic circuit diagram of a conventional flip flop register used in a scan chain apparatus.

FIG. 3 illustrates a schematic circuit diagram of one embodiment of a flip flop register used in a scan chain apparatus in accordance with the principles of the present invention.

### DETAILED DESCRIPTION OF THE PREFERRED EMBODIMENT

The present invention provides a scan flip flop apparatus capable of performing scan tests at speed and applying the scan tests to a speed path of a circuit. The speed path of a circuit can be tested in a single clock cycle. The present invention also solves the problems of the increase in power dissipation and circuit temperature caused by the activities within a circuit during shifting of scan vectors through a scan chain. The scan flip flop apparatus prevents propagation of signals from the scan flip-flop apparatus into a circuit under test during a scan shift or scan-enable operation. The scan flip flop apparatus prevents propagation of spurious data through the circuit and enables the scan-in of scan test vectors to be performed at speed, i.e. the speed that the circuit is designed to operate.

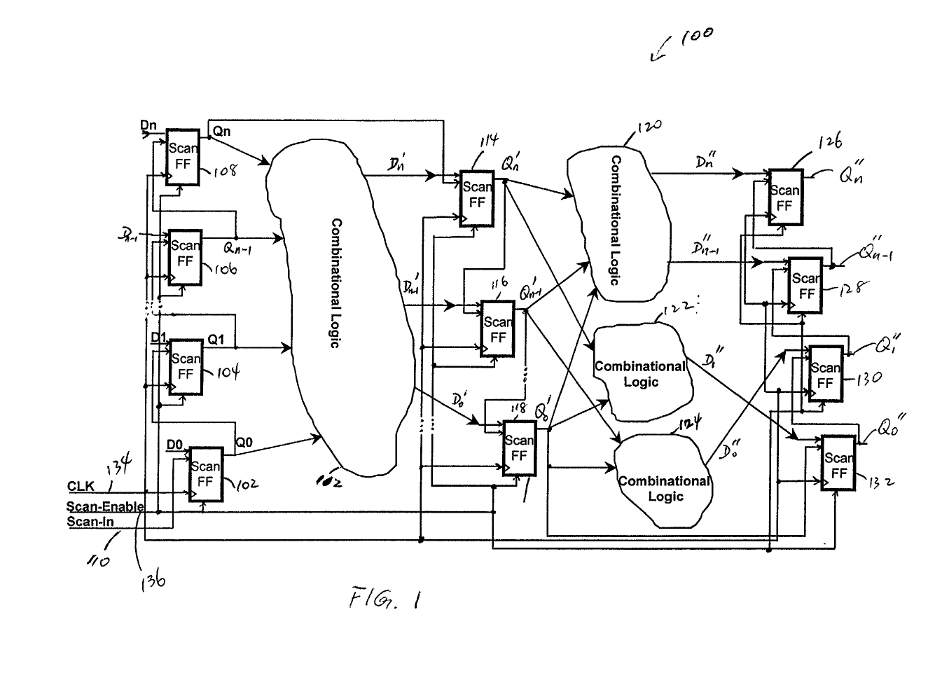

FIG. 1 illustrates one embodiment of a scan chain 100 used in a Design-for-Test (DFT) system. The scan chain 100 includes a plurality of flip flop registers 102, 104, 106, 108. The number of flip flop registers can be varied within the scope of the present invention. The flip flop registers 102, 104, 106, 108 are connected in series, whereby an output Q₀ of the flip flop register 102 is sent to a scan-in input of the flip flop register 104. Similarly, an output Q₁ of the flip flop register 104 is sent to a scan-in input of the next flip flop register (not shown). A scan-in input of the flip flop register 106 is connected to an output of a previous flip flop register (not shown). An output Qₙ₋₁ of the flip flop register 106 is sent to a scan-in input of the flip flop register 108.

In FIG. 1, the scan chain 100 shifts scan test data or test vectors from a scan-in line 110 into a combinational logic 112 of a circuit under test via the flip flop registers 102, 104, 106, 108. Each of the flip flop registers 102, 104, 106, 108 sends its output, Q₀, Q₁ . . . Qₙ₋₁, Qₙ, to the combinational logic 112 and retrieves test results, Dₙ′, D_{n-1′}, and D₀′ from the combinational logic 112 via a plurality of flip flop registers 114, 116, 118. The number of the retrieving flip flop registers can be varied within the scope of the present invention. These retrieving flip flop registers 114, 116, 118 are connected in the scan chain 100 in series. An output Qₙ of the flip flop register 108 is sent to a scan-in input of the flip flop register 114. Similarly, an output Q_{n′ of the flip flop register 114 is sent to a scan-in input of the flip flop register 116. An output Q}ₙ₋₁′ of the flip flop register 116 is sent to a scan-in input of the next flip flop register (not shown). A scan-in input of the flip flop register 118 is connected to an output of a previous flip flop register (not shown).

Also shown in FIG. 1, the circuit may include a plurality of additional combinational logics 120, 122, 124. The number of combinational logics can be varied within the scope of the present invention. The number of additional combinational logics may represent the complexity of a circuit under test. For example, if the circuit has only the combinational logic 112, the flip flop registers 114, 116, 118 can be used as scan-out flip flop registers such that the output Dₙ′, Dₙ₋₁′, and D₀ are shifted out via the flip flop registers 114, 116, 118.

As shown in FIG. 1, the flip flop registers 114, 116, 118 are also used as scan-in flip flop registers for the combinational logics 120, 122, 124. The scan chain 100 shifts scan test data or test vectors from the scan-in line 110 into the combinational logics 120, 122, 124 via the flip flop registers 114, 116, 118. The flip flop registers 114, 116, 118 send their outputs, Qₙ′, Qₙ₋₁′, and Q₀′, to the combinational logics 120, 122, 124 and retrieve test results, Dₙ″, Dₙ₋₁″, D₁″, D₀″ from the combinational logics 120, 122, 24 via a plurality of flip flop registers 126, 128, 130, 132. The number of the retrieving flip flop registers can be varied within the scope of the present invention.

The retrieving flip flop registers 126, 128, 130, 132 are also connected in the scan chain 100 in series. As shown, an output Q₀′ of the flip flop register 118 is sent to a scan-in input of the flip flop register 132. Similarly, an output Q_{0″ of the flip flop register 132 is sent to a scan-in input of the flip flop register 130. An output Q}_{1′ of the flip flop register 130 is sent to a scan-in input of the next flip flop register, e.g. the flip flop register 128. An output Q}ₙ₋₁″ of the flip flop register 128 is sent to a scan-in input of the flip flop register 126.

Also shown in FIG. 1, the flip flop registers are clocked by a CLK signal 134. A scan-in test operation is enabled by a Scan-Enable signal 136.

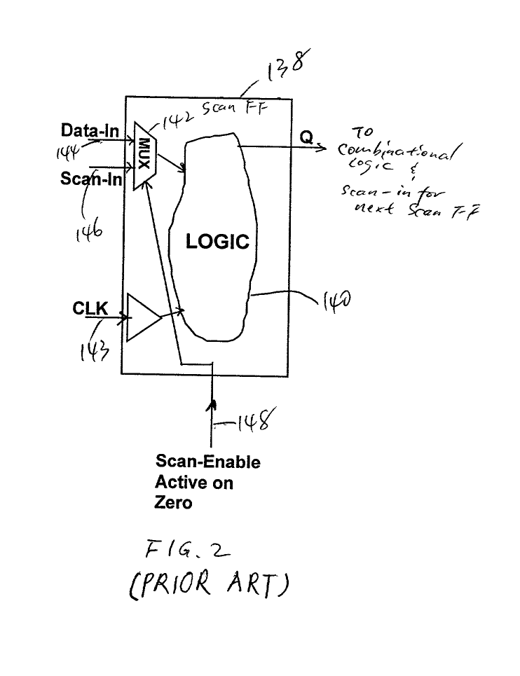

FIG. 2 illustrates a schematic circuit diagram of a conventional flip flop register 138 used in a scan chain apparatus. The register 138 includes a logic 140 and a mux 142. The logic 140 represents the logic of a flip flop register and is known in the art and is clocked by a CLK signal 143. The mux 142 selectively passes either a signal on a Data-In line 144 or a signal on a Scan-In line 146 to the logic 140. The mux 142 is controlled by a Scan-Enable signal 148. The Scan-Enable signal 148 is set to either allow the signal on the Data-In line 144 to pass to the logic 140 or allow the signal on the Scan-In line 146 to pass to the logic 140. In one embodiment as shown in FIG. 2, when the Scan-Enable signal 148 is logic Zero, the Scan-In line 146 is active, i.e. the signal on the Scan-In line 146 passes to the logic 140. An output Q is sent to a circuit under test, e.g. the combinational logic of the circuit as shown in FIG. 1. The output Q is also sent to a Scan-In line of a next scan-in flip flop register.

In this conventional scan chain design, whenever a scan shifting occurs, the outputs of the flip flop registers are input into the combinational logics. This creates a lot of circuit activities in the combinational logic and causes a tremendous increase in power consumption and the circuit temperature. Thus, typically, the scan shifting has to be performed at much slower speed, for example, at one tenth of the maximum circuit speed. Therefore, speed testing of a circuit cannot be performed, e.g. in a single clock cycle.

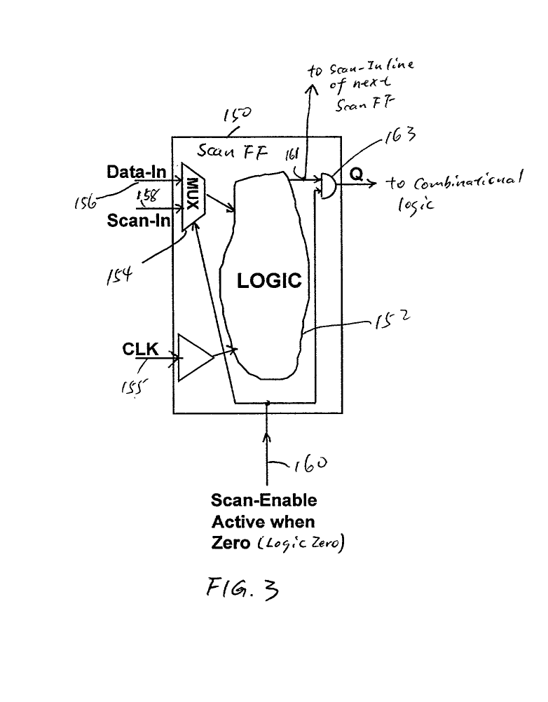

FIG. 3 illustrates a schematic circuit diagram of one embodiment of a flip flop register 150 used in a scan chain apparatus in accordance with the principles of the present invention. The register 150 includes a logic 152 and a mux 154. The logic 152 represents the logic of a flip flop register and is known in the art and is clocked by a CLK signal 155. The mux 154 selectively passes either a signal on a Data-In line 156 or a signal on a Scan-In line 158 to the logic 152. The mux 154 is controlled by a Scan-Enable signal 160. The Scan-Enable signal 160 is set to either allow the signal on the Data-In line 156 to pass to the logic 152 or allow the signal on the Scan-In line 158 to pass to the logic 152. In one embodiment as shown in FIG. 3, when the Scan-Enable signal 160 is logic Zero, the Scan-In line 158 is active, i.e. the signal on the Scan-In line 158 passes to the logic 152. An output 161 of the logic 152 is sent to a Scan-In line of a next scan-in flip flop register. Also, the output 160 is sent to a logic device 163, such as an AND gate ANDing with the Scan-Enable signal 161, to generate an output Q. When the scan-in is active, the Scan-Enable is logic Zero, and the output Q is logic Zero. The output Q is sent to a circuit under test, e.g. the combinational logic of the circuit as shown in FIG. 1.

In FIG. 3, whenever a scan shifting occurs, the flip flop register disables any change in the output to the combinational logic because the Scan-Enable signal 160 is logic Zero. Thus, no signals get propagated through the combinational logic. Therefore, there is no circuit activity in the combinational logic, thereby no increasing in power usage and/or heating of the circuit. As a result, scan shifting can be performed at a circuit clock speed. This allows speed testing to be performed. In other words, a scan operation (scan in and scan out of test data) can be performed at the speed that a circuit device is designed to operate.

It is appreciated that the other types of logic devices, such as NAND gate, etc., can be used within the scope of the present invention to result in a logic Zero output to the combinational logic such that there is no activity in the combinational logic during a scan shift. It is also appreciated that the Scan-Enable signal can be active when logic One in conjunction with using a NOR gate and an inverse gate to result in a logic Zero output to the combinational logic within the scope of the present invention.

The foregoing description of the exemplary embodiment of the invention has been presented for the purposes of illustration and description. It is not intended to be exhaustive or to limit the invention to the precise form disclosed. Many modifications and variations are possible in light of the above teaching. It is intended that the scope of the invention be limited not with this detailed description, but rather by the claims appended hereto.

What is claimed is:

1. A flip flop apparatus used in a scan chain, comprising:
a flip flop logic clocked by a clock signal;
a mux for muxing a data-in signal and a scan-in signal and outputting either the data-in signal when a scan-enable control signal enables the data-in signal during a data-enable operation or the scan-in signal when the scan-enable control signal enables the scan-in signal during a scan-enable operation, an output of the mux being sent to the flip flop logic;
a logic device having a first input which receives an output of the flip flop logic and a second input which receives the scan-enable control signal; and
wherein during the scan-enable operation, an output of the logic device is logic Zero.

2. The apparatus of claim 1, wherein the logic device is an AND gate.

3. The apparatus of claim 1, wherein during the data-enable operation, the output of the logic gate is the output of the flip flop logic.

4. A scan chain apparatus, comprising:
at least three flip flop registers connected in series;
at least one combinational logic connected to the at least three flip flop registers for receiving/sending signals from/to the flip flop registers;
each of the flip flop registers comprising:
a flip flop logic clocked by a clock signal;
a mux for muxing a data-in signal and a scan-in signal and outputting either the data-in signal when a scan-enable control signal enables the data-in signal during a data-enable operation or the scan-in signal when the scan-enable control signal enables the scan-in signal during a scan-enable operation, an output of the mux being sent to the flip flop logic;
a logic device having a first input which receives an output of the flip flop logic and a second input which receives the scan-enable control signal, the output of one of the flip flop registers is serially connected to the scan-in signal of another flip flop register, an output of the logic device being sent to the combinational logic; and
wherein during the scan-enable operation, the output of the logic device is logic Zero.

5. The apparatus of claim 4, wherein the logic device is an AND gate.

6. The apparatus of claim 4, wherein during the data-enable operation, the output of the AND gate is the output of the flip flop logic.

7. A method of testing a circuit at speed in a scan chain apparatus, comprising the steps of:
providing a plurality of flip flop registers connected in series;
shifting test data into a combinational logic of the circuit via the flip flop registers;
outputting logic Zero from the flip flop registers to the combinational logic during a scan-enable operation; and
outputting a flip flop logic from the flip flop registers to the combinational logic during a data-enable operation.

8. The method of claim 7, wherein the step of outputting logic Zero includes providing an AND gate, and the AND gate outputs logic Zero during the scan-enable operation.
